(19) United States
(12) Patent Application Publication
(10) Pub. No.: US 2026/0225207 A1
(43) Pub. Date: Aug. 6, 2026

(54) BLEED AND FEED METHOD FOR SLURRY RECYCLING

(71) Applicant: Applied Materials, Inc., Santa Clara, CA (US)

(72) Inventors: Jamie Stuart LEIGHTON, Palo Alto, CA (US); Miroslav GELO, Oakley, CA (US); Robert NAVASCA, Redwood City, CA (US); John Howard GIVENS, Pflugerville, TX (US); Bryce MILLER, Hillsboro, OR (US); John Anthony GARCIA, San Jose, CA (US)

(21) Appl. No.: 19/047,355

(22) Filed: Feb. 6, 2025

(51) Int. Cl. B24B 57/02; B24B 37/04; H01L 21/306

(52) U.S. Cl. CPC B24B 57/02; B24B 37/042; H10P 52/402

(57) ABSTRACT

Embodiments of the present disclosure generally relate to planarization of surfaces on substrates. More specifically, embodiments of the present disclosure relate to methods and systems for polishing a substrate. In one or more embodiments, the method includes polishing a device side of the substrate in the presence of a first polishing fluid, the first polishing fluid comprising a first ratio of recycled slurry to new slurry; and polishing the device side of the substrate in the presence of a second polishing fluid, the second polishing fluid comprising a second ratio of recycled slurry to new slurry that is smaller than the first ratio of recycled slurry to new slurry.

### BACKGROUND

### Field

Embodiments described herein generally relate to systems and methods used to process semiconductor substrates in an electronic device manufacturing process. More particularly, embodiments of the present disclosure relate to methods for polishing or planarization of surfaces on substrates and to systems related thereto.

### Description of the Related Art

Chemical mechanical polishing (CMP) is commonly used in the manufacturing of high-density integrated circuits, e.g., semiconductor devices, to planarize or polish a layer of material deposited on a substrate. A typical CMP process includes contacting the material layer of the substrate to be planarized with a polishing pad and moving the polishing pad, the substrate, or both, hence creating relative movement between the material layer surface and the polishing pad, in the presence of a polishing fluid. Material is removed across the material layer surface in contact with the polishing pad through a combination of chemical and mechanical activity, which is provided at least in part by the polishing fluid. Commonly used polishing fluids include abrasive particle-containing slurries, e.g., colloids or suspensions, reactive liquid (abrasive-free) slurries, and abrasive-free or reduced-abrasive polishing fluids used in conjunction with fixed-abrasive polishing pads having abrasive particles disposed therein.

Typically, polishing fluids are highly engineered to provide desired chemical and mechanical polishing performance characteristics and to disperse and keep the abrasive particles in a colloid or a relatively stable suspension. At least in part due to high costs of engineering and manufacturing CMP fluids, CMP processes are often the most expensive substrate processing operations in the manufacturing of semiconductor devices.

Accordingly, in order to reduce costs associated with polishing fluids used in semiconductor device manufacturing, there is a need in the art for improved methods and systems for polishing of surfaces on substrates during semiconductor substrate polishing process.

### SUMMARY

Embodiments of the present disclosure generally relate to planarization of surfaces on substrates. More specifically, embodiments of the present disclosure relate to methods and systems for polishing a substrate.

Embodiments of the present disclosure provide a method of polishing a device side of a substrate in a polisher in the presence of a first polishing fluid, the first polishing fluid comprising a first ratio of recycled slurry to new slurry; and polishing the device side of the substrate in the presence of a second polishing fluid, the second polishing fluid comprising a second ratio of recycled slurry to new slurry that is smaller than the first ratio of recycled slurry to new slurry.

Embodiments of the present disclosure may further provide a method of polishing a device side of a substrate, the method include polishing the device side of the substrate in the presence of a first polishing fluid, the first polishing fluid comprising a first ratio of recycled slurry to new slurry; and polishing a back side of the substrate in the presence of a second polishing fluid, the second polishing fluid comprising a second ratio of recycled slurry to new that is higher than the first ratio of recycled slurry to new slurry.

Embodiments of the present disclosure further provide a substrate polishing system. The substrate polishing system includes one or more polishers, each having a polishing pad disposed on a platen; one or more slurry delivery systems operable to control a ratio of recycled slurry to new slurry delivered to each polishing pad; and a controller coupled to the one or more polishers and to the one or more slurry delivery systems. The controller comprising one or more processors and one or more non-transitory machine readable media storing instructions that when executed by the one or more processors cause the substrate polishing system to: polish a substrate in the presence of a first polishing fluid, the first polishing fluid comprising a first ratio of recycled slurry to new slurry; and polish the substrate in the presence of a second polishing fluid, the second polishing fluid comprising a second ratio of recycled slurry to new slurry that is different than the first ratio of recycled slurry to new slurry.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a top view of a semiconductor substrate chemical mechanical polishing system having a cleaning system, according to one or more embodiments of the present disclosure.

FIG. 2 is a schematic sideview of a polishing system, according to one or more embodiments of the present disclosure.

FIGS. 3A and 3B are schematic diagrams of slurry delivery systems or polishing fluid delivery systems, according to one or more embodiments of the present disclosure.

FIG. 4 is a schematic diagram of a polishing fluid delivery module of a polishing fluid delivery system, according to one or more embodiments of the present disclosure.

FIG. 5 illustrates a block diagram of a process for substrate surface polishing, according to one or more embodiments of the present disclosure.

FIG. 6 illustrates a block diagram of a process for substrate surface polishing, according to one or more embodiments of the present disclosure.

In order to facilitate understanding, identical reference numerals have been used where possible to designate identical elements that are common to the figures. It is contemplated that the elements and features of each embodiment may be beneficially incorporated into the other embodiments without further recitation.

### DETAILED DESCRIPTION

Embodiments of the present disclosure relate to methods and systems for chemical mechanical polishing (CMP) of a substrate in an electronic device manufacturing process.

CMP is commonly used in the manufacture of high-density integrated circuits to planarize or polish a layer of material deposited on a substrate. CMP is useful in removing undesired surface topography and surface defects, such as rough surfaces, agglomerated materials, crystal lattice damage, scratches, and contaminated layers or materials. CMP is also useful in forming features on a substrate by removing excess material deposited to fill the features, and to provide an even surface for subsequent patterning operations.

In conventional CMP techniques, a substrate carrier or polishing head mounted on a carrier assembly positions a substrate secured therein in contact with a polishing pad mounted on a platen in a CMP apparatus. The carrier assembly provides a controllable load, i.e., pressure on the substrate to urge the substrate against the polishing pad. An external driving force moves the polishing pad relative to the substrate. Thus, the CMP apparatus creates polishing or rubbing movement between the surface of the substrate and the polishing pad while dispersing a polishing composition, or slurry, to affect both chemical activity and mechanical activity.

The dispersed polishing composition, or slurry, is distributed radially outward from the dispense location by the centrifugal force imparted to the polishing fluid from the rotation of the platen. When the polishing fluid reaches the circumferential edge of the polishing pad, the polishing fluid typically flows into a drainage basin that surrounds the platen and extends into a region disposed below the platen. This facilitates capture of all of the fluids and other processing byproducts used during a CMP substrate process and other processing activities concomitant wherewith, e.g., pad rinsing and pad conditioning activities, as well as polishing byproducts related thereto.

In an effort to reduce the high costs of engineering and manufacturing CMP polishing fluids, the use of recycled polishing fluids in CMP processes has been largely unsuccessful, at least in part due to the difficulties determining a favorable ratio of new slurry to recycled slurry during processing, as it can lead to degradation of removal rate and surface quality of the polished substrate resulting in a lower yield or re-work required. Beneficially, embodiments provided herein provide methods and a system to achieve improved cost and increased performance of the CMP of substrates by selectively adjusting a ratio of new slurry to recycled slurry during the processing of substrates in electronic device manufacturing processes.

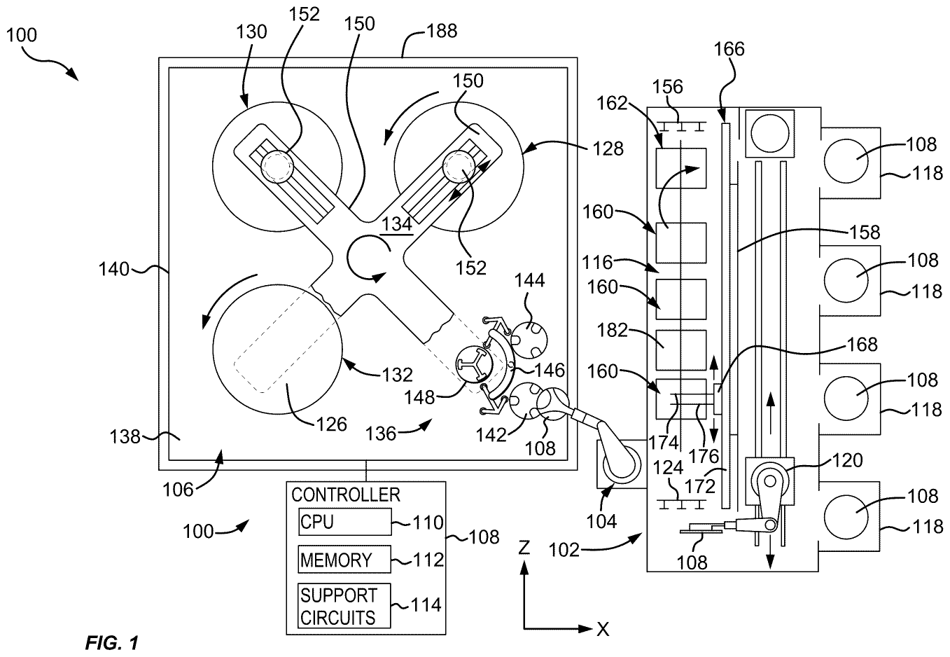

FIG. 1 illustrates a top view of a semiconductor substrate chemical mechanical polishing (CMP) system 100 having a polishing module 106 that includes at least one CMP station. In the implementation depicted in FIG. 1, the polishing module 106 includes a plurality of CMP stations, illustrated as a first station 128, a second station 130, and a third station 132 disposed in an environmentally controlled enclosure 188. The first station 128, the second station 130, and the third station 132 include conventional CMP stations configured to perform an oxide planarization process utilizing an abrasive containing polishing fluid. It is contemplated that CMP processes to planarize other materials may be alternatively performed, including the use of other types of polishing and/or polishing fluids.

The exemplary polishing module 106 also includes a transfer station 136 and a carousel 134 that are disposed on an upper or first side 138 of a machine base 140. In one implementation, the transfer station 136 includes an input buffer station 142, an output buffer station 144, a transfer robot 146, and a load cup assembly 148. The loading robot 104 is configured to retrieve substrates from the input module 124 and transfer the substrates 108 to the input buffer station 142. The loading robot 104 is also utilized to return polished substrates from the output buffer station 144 to the input module 124, from where the polished substrates are then advanced through the cleaning system 116 prior to being returned to the cassettes 118 coupled to the factory interface 102 by the interface robot 120. The transfer robot 146 is utilized to move substrates between the buffer stations 142, 144 and the load cup assembly 148.

In one or more embodiments, the transfer robot 146 includes two gripper assemblies, each having pneumatic gripper fingers that hold the substrate by the substrate's edge. The transfer robot 146 may simultaneously transfer a substrate to be processed from the buffer station 142 to the load cup assembly 148 while transferring a processed substrate from the load cup assembly 148 to the output buffer station 144.

The carousel 134 is centrally disposed on the base 140. The carousel 134 typically includes a plurality of arms 150, each supporting a polishing head 152. Two of the arms 150 depicted in FIG. 1 are shown in phantom such that a planarizing surface of a polishing pad 126 of the third station 132 and the transfer station 136 may be seen. The carousel 134 is indexable such that the polishing head assemblies 152 may be moved between the planarizing stations 128, 130, 132 and the transfer station 136.

A controller 111 is provided to facilitate control and integration of the modules of the CMP system 100. The controller 111 comprises a central processing unit (CPU) 110, a memory 112, and support circuits 114. The controller 111 is coupled to the various components of the CMP system 100 to facilitate control of, for example, the polishing, cleaning, storing, and transfer processes.

The factory interface 102 generally includes an interface robot 120 and one or more substrate cassettes 118. The interface robot 120 is employed to transfer substrates 108 between the substrate cassettes 118, a cleaning system 116, and an input module 124. The input module 124 is positioned to facilitate transfer of substrates 108 between the polishing module 106 and the factory interface 102 as will be further described below.

The cleaning system 116 removes polishing debris, abrasives, polishing fluid, and/or excess deposited material from the polished substrates that remains after polishing and between the polishing of substrates. The cleaning system 116 includes a plurality of cleaning modules 160, a substrate handler 166, a dryer 162, and an output module 156. The substrate handler 166 retrieves a processed substrate 108 returning from the polishing module 106 from the input module 124 and transfers the substrate 108 through the plurality of cleaning modules 160 and dryer 162. The dryer 162 dries substrates existing the cleaning system 116 and facilitates substrate transfer between the cleaning system 116 and the factory interface 102 by the interface robot 120.

In operation, the CMP system 100 is initiated with the substrate 108 being transferred from one of the cassettes 118 to the input module 124 by the interface robot 120. The loading robot 104 then moves the substrate from module 124 to the transfer station 136 of the polishing module 106. The substrate 108 is loaded into the polishing head 152 moved over and polished against the polishing pad 126 while in a horizontal orientation. Once the substrate is polished, polished substrates 108 are returned to the transfer station 136 from where the robot 104 may transfer the substrate 108 from the planarizing module 106 to the input module 124. The substrate handler 166 then retrieves the substrate from the input module 124 transfers the substrate through the cleaning modules 160 of the cleaning system 116. When the polishing process is complete, once cleaned, the cleaned substrate 108 is transferred to the output module 156. In one or more embodiments, additionally, or alternatively, if the polishing process has not been completed, the cleaned substrate 108 is transferred to a queuing station such as the input module 124 to await a subsequent transfer from the input module 124 to the transfer station 136 of the planarizing module 106 to complete the polishing process. Once the polishing process is completed, the cleaned substrate 108 is returned to one of the cassettes 118 by the interface robot 120 while returning the cleaned substrate 108 to a horizontal orientation. Optionally, the interface robot 120 may transfer the cleaned substrate to the metrology system 180 prior to the substrate's return to the cassette 118.

Although any suitable substrate handler may be utilized, the substrate handler 166 depicted in FIG. 1 includes a robot 168 having at least one gripper (two grippers 174, 176 are shown) that is configured to transfer substrates between the input module 124, the cleaning modules 160 and the dryer 162. Optionally, the substrate handler 166 may include a second robot (not shown) configured to transfer the substrate between the last cleaning module 160 and the dryer 162 to reduce cross contamination.

In one or more embodiments as depicted in FIG. 1, the substrate handler 166 includes a rail 172 coupled to a partition 158 separating the cassettes 118 and interface robot 120 from the cleaning system 116. The robot 168 is configured to move laterally along the rail 172 to facilitate access to the cleaning modules 160, dryer 162 and the input and output modules 124, 156.

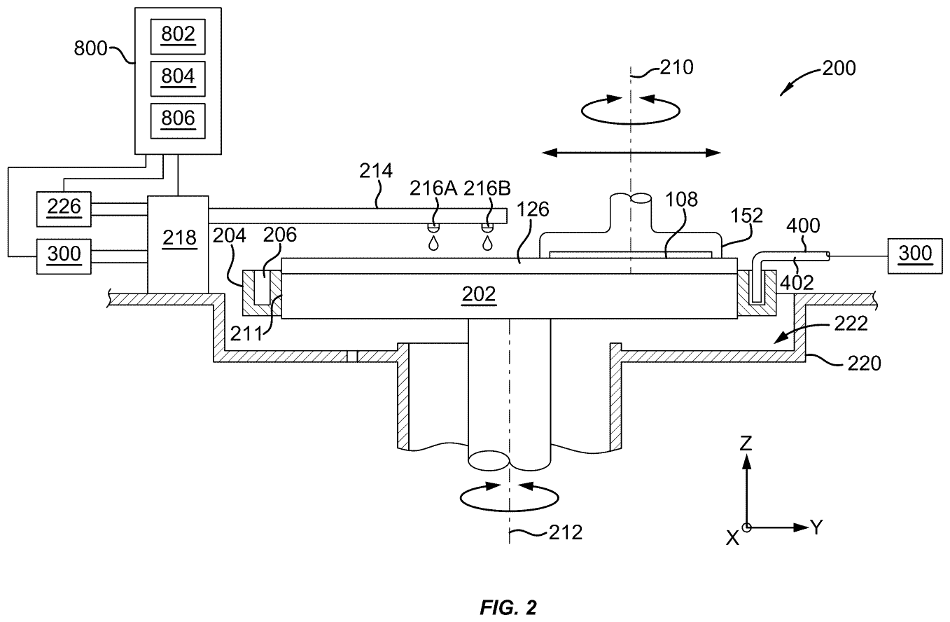

FIG. 2 is a schematic side view of a polishing system 200 (e.g., the polishing station 128, 130, or 132 within the polishing module 106 of the CMP system 100 shown in FIG. 1) according to one or more embodiments of the present disclosure. Here, the polishing system 200 includes a cylindrical platen 202, a polishing pad 126 secured to the platen, e.g., by use of a pressure-sensitive adhesive, a substrate carrier 152 disposed above the platen 202 to face the polishing pad 126, and a catch basin 204 used to collect and recycle polishing fluid from the polishing process. The catch basin 204 is sized to surround and to abut the polishing pad 126 and rotates about a platen axis 212 with the polishing pad 126. In one or more embodiments, the catch basin 204 includes a U-shaped cross section (defined by the inner walls) that define a trough 206 that collects all of the polishing fluid that flows radially outwards from the surface of the polishing pad 126, thus preventing the polishing fluid desired for reuse to fall between the catch basin 204 and the polishing pad 126. Additionally, or alternatively, the fluid that is undesirable for reuse flows through a gap created by a lip (not shown) on a wall 211 of the catch basin 204 immediately adjacent to polishing pad 126 disposed on the platen 202 into a drainage basin 222 by means of an actuator configured to raise the catch basin 204 in the Z direction. When polishing fluid desired for reuse is dispensed onto the polishing pad 126, the catch basin 204 is lowered into a fluid collection position and the desired polishing fluid for reuse is collected for reuse during the polishing process.

During a typical CMP process, the substrate carrier 152 urges a material surface of a substrate 108 disposed in the substrate carrier 152 against the polishing pad 126 while simultaneously rotating about a carrier axis 210. The platen 202 rotates about the platen axis 212 while the rotating substrate carrier 152 sweeps back and forth from an inner diameter to an outer diameter of the platen 202 to, in part, reduce uneven wear of the polishing pad 126. In one or more embodiments, the polishing system 200 may further include a pad conditioner assembly (not shown) that is used to abrade, rejuvenate, and remove polish byproducts or other debris from the surface of the polishing pad 126.

Polishing fluids, polishing fluid additives, cleaning fluids, and/or deionized (DI) water are delivered to a fluid dispense arm 214 positioned over the platen 202 from a polishing fluid source 226 and are dispensed onto the polishing pad 126 using nozzles 216A and 216B positioned in the fluid dispense arm 214. In one or more embodiments, the nozzle 216A is configured to deliver an amount of new slurry to the polishing pad 126 while the nozzle 216B is configured to deliver an amount of recycled slurry to the polishing pad 126. The fluid dispense arm 214 is coupled to an actuator 218, which positions the fluid dispense arm 214 over the platen 202 by swinging the fluid dispense arm 214 thereover. The actuator 218 is disposed on the base plate 220 that surrounds the platen 202.

The catch basin 204 further includes a vacuum device 400. The vacuum device 400 includes a suction tube 402. The catch basin 200 does not include a gravity type drain or opening that can be used to drain polishing fluids from the trough 206. Fluid collection efficiency of gravity drain systems can be inadequate owing to the liquid dispersing over large surface areas, resulting in slow drainage. The suction tube 402 is disposed within the trough 206 of the catch basin 200, thus facilitating the extraction of polishing fluids from the trough 206 by use of the suction tube 402. The vacuum device 400 is configured to be stationary in relation to the rotating catch basin 204, although it is conceived that the tube may have ability for control of its movement by actuation devices to optimize fluid collection or remove the collection tube for service. The vacuum device 400 is supported by a portion of the polishing system 200 that does not rotate with the platen 202, such as by use of a bracket (not shown) clamped or attached to one of the walls of the U-shape catch basin 204. As the polishing fluid flows from the polishing pad 126 and into the trough 206, the vacuum device 400 draws the polishing fluid out of the trough 206.

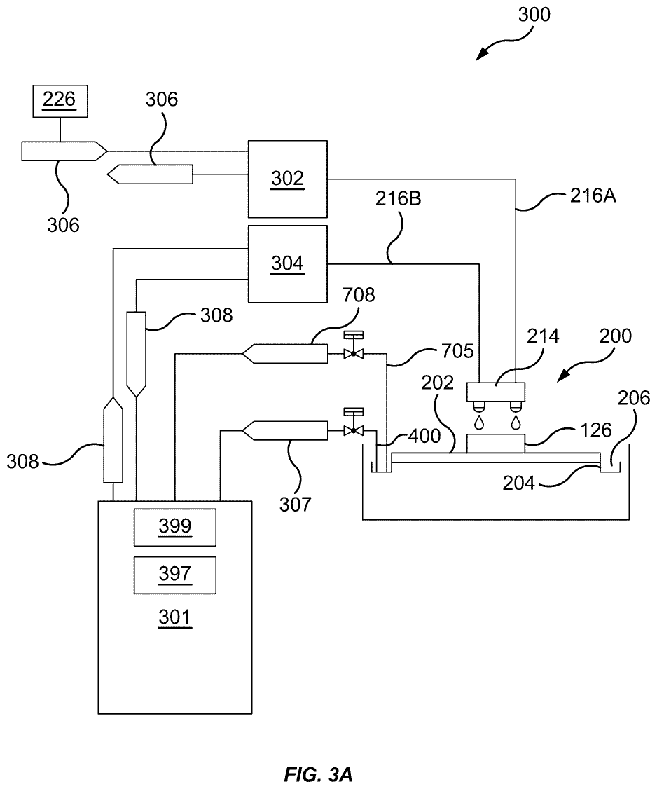

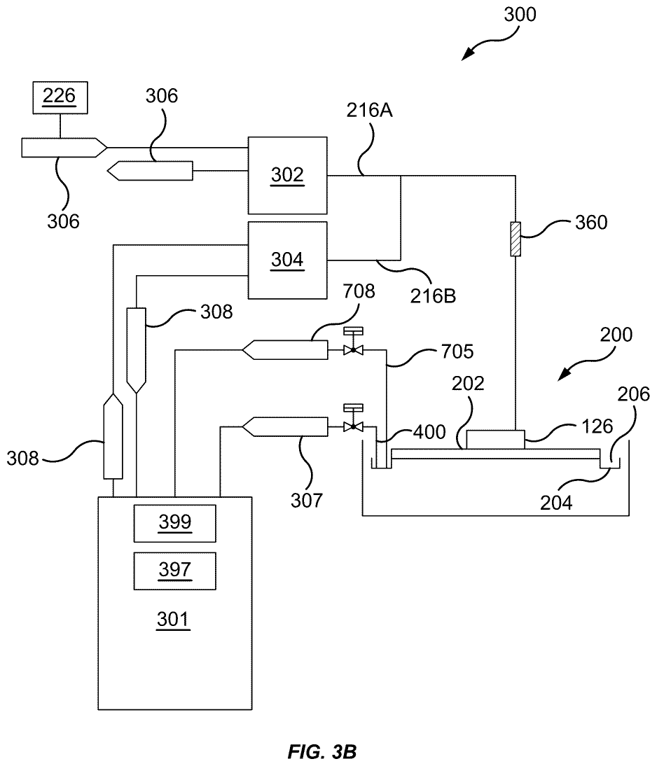

Referring to FIG. 3A, a polishing fluid or slurry delivery system 300 is shown. The slurry delivery system 300 includes a polishing fluid or slurry recycle module 301 and one or more polishing systems 200. The slurry delivery system 300 further comprises a first slurry delivery system 302 and a second slurry delivery system 304. The first slurry delivery system 302 delivers a first polishing fluid 306 from a polishing fluid 226 through the nozzle 216A within the fluid dispense arm 214 to the polishing pad 126 of the polishing system 200. The polishing fluid source 226 comprises a centralized or local polishing fluid distribution system used by a manufacturing facility to deliver the first polishing fluid 306 to the polishing system 200. In one or more embodiments, the first polishing fluid 306 from the polishing fluid source 226 has not yet been used in a CMP operation, and thus it will be referred from hereon as new slurry 306. The new slurry 306 is then collected by the catch basin 204 and drawn out of the catch basin 204 by the vacuum device 400, and a second vacuum device 705 disposed within the trough 204 of the catch basin 206. The used slurry 307 is then sent to the recycled module 301. The vacuum device 400 is configured to collect the used slurry 307 drawn out of the trough 206 during the slurry polishing process. The second vacuum device 705 is configured to collect waste fluids 708 drawn out of the trough 206 during a period that rinse, or cleaning fluids are flowing after or before the slurry polishing process.

The polishing fluid recycle module 301 collects the used slurry 307 extracted from the trough 206 of the catch basin 204 through the vacuum device 400 and recycles/filters the used slurry 307 (i.e., the first polishing fluid) to make a second polishing fluid 308, which will be referred to as recycled slurry 308 from hereon. The second polishing fluid or recycled slurry 308 is then provided to the second slurry delivery system 304 for delivery to the polishing pad 126. When the recycled slurry 308 is delivered to the polishing pad 126, flow of the new slurry 306 may be stopped by the first slurry delivery system 302 such that the slurry delivery system 300 may operate continuously with the recycled slurry 308. Alternatively, as will be discussed later in detail, the flow rate of the new slurry 306 through nozzle 216A and the flow rate of the recycled slurry 308 through nozzle 216B may be adjusted to provide a mixture or ratio of new slurry 306 and recycled slurry 308 to the polishing pad 126. This allows the new slurry 306 to provide for any losses in the collection process and for preferential process tuning of the blend ratio of the new slurry 306 and recycled slurry 308 for improved substrate 108 polishing.

In one or more embodiments, as shown in FIG. 3B, the slurry delivery system 300 includes a static mixer 360 to premix the new slurry 306 and the recycled slurry 308 prior to delivery of the polishing fluid ratio or blend to the polishing pad 126.

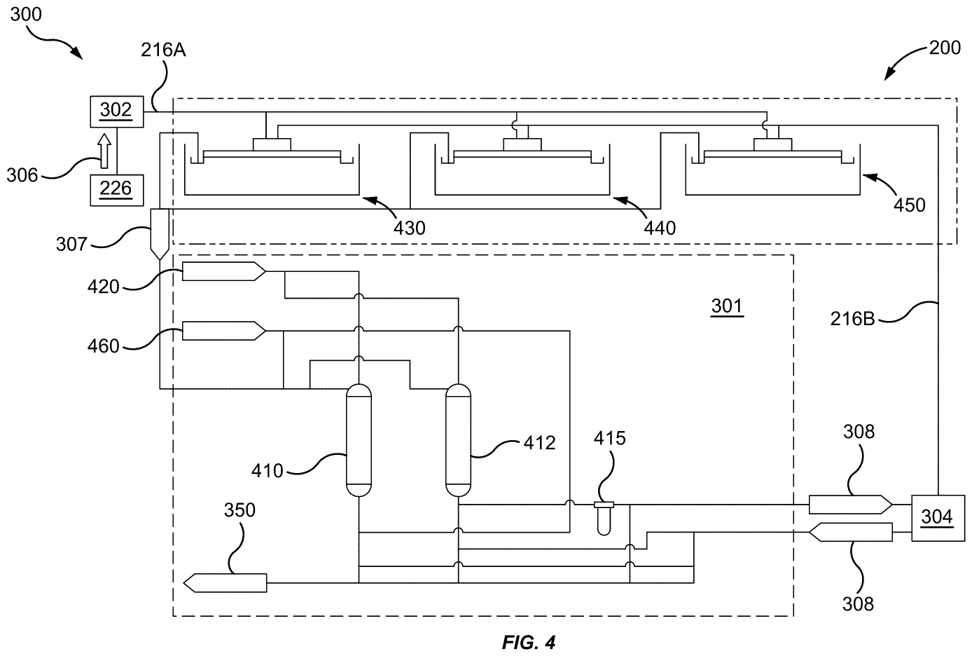

In one or more embodiments, as shown in FIG. 4, the polishing fluid recycle module 301 further comprises a first tank 410 and a second tank 412. A vacuum generator 420 provides vacuum suction to the first tank 410 and enables the used slurry 307 to be drawn into the polishing fluid recycle module 301 to be processed into recycled slurry 308 by filtering and processing of the polishing fluid. Initially, the first tank 410 is filled with the used slurry 307, while the second tank 412 is empty. Once the first tank 410 has been filled with used slurry 307, the vacuum generator 420 switches to pressure delivery mode to pressurize the first tank 410 and enable the used slurry 307 to be moved around the polishing fluid recycle module 301 into the second tank 412 for holding and to provide agitation to the used slurry 307. The vacuum generator 420 may utilize gas (i.e., nitrogen or other gas) to push the used slurry 307 from the first tank 410 to the second tank 412. In one or more embodiments, the vacuum generator 420 may be a Venturi system. The used slurry 307 is in continuous motion in order to keep the used slurry 307 in suspension. The transfer of the used slurry 307 from first tank 410 to second tank 412 dispenses the fluid around the polishing fluid recycle module 301 to the second slurry delivery system 304, at which point the second slurry delivery system 304 may consume a portion or all of the used slurry 307 and deliver it as recycled slurry 308 to the polishing system 200. Particulate matter with particle size greater than the particle size of the polishing fluid is filtered out of the used slurry 307 by addition of a filter 415 during the recirculation process to move fluid from first tank 410 to second tank 412. The used slurry 307, now processed into recycled slurry 308, flows from the filter 415 to the second slurry delivery system 304 and to polishing system 200. In one or more embodiments, the polishing fluid recycle module 301 further comprises a first clean valve 460, the first clean valve 460 is configured to be opened in order to enable flushing and cleaning of the slurry delivery system 300 during maintenance.

In one or more embodiments, as shown in FIG. 4, the polishing system 200 incorporates multiple platens, e.g., first polishing platen 430, second polishing platen 440, and a third polishing platen 450. These multiple platens may be located within the polishings stations 128, 130, and 132 within the planarizing module 106 forming part of the CMP system 100 shown in FIG. 1. The polishing fluid recycle module 301 may interact with these platens to collect polishing fluid for one platen, all platens, or a combination thereof. This allows for flexibility to collect the polishing fluid from specific processes only or alternatively, to maximize collection of polishing fluid from all platens simultaneously. The delivery of the recirculated fluids (i.e., recycled slurry 308) to the second slurry delivery system 304 may be dispensed to just one platen, all platens, or a combination thereof.

In one or more embodiments, the recycled slurry 308 collected using the slurry delivery system 300 and the new slurry 306 from the polishing fluid source 226 are sequentially dispensed onto the surface of the polishing pad 126. In some embodiments, the substrate 108 is first polished using the recycled slurry 308 collected using the slurry delivery system 300 before being polished using the new slurry 306 from the polishing fluid source 226, or vice versa. In at least one embodiment, one side of the substrate 108 is polished using only the recycled slurry 308 collected using the slurry delivery system 300 for a first time period before being polished for a second time period using only the new slurry 306 from the polishing fluid source 226. Polishing the substrate 108 with only the new slurry 306 from the polishing fluid source 226 for the second period ensures that any possible defects to the substrate 108 surface caused by trace contaminants or agglomerations in the recycled slurry 308 collected using the slurry delivery system 300 are removed from the substrate 108 surface. In one or more embodiments, dispensing the recycled slurry 308 collected using the slurry delivery system 300 is alternated with dispensing the new slurry 306 from the polishing fluid source 226. In one or more embodiments, the new slurry 306 from the polishing fluid source 226 is mixed with the recycled slurry 308 collected using the slurry delivery system 300 before being delivered to the polishing surface of the polishing pad 126. Additionally, or alternatively, the flow rate of nozzle 216A of the new slurry 306 from the polishing fluid source 226 and the flow rate of nozzle 216B of the recycled slurry 308 collected using the slurry delivery system may be adjusted to provide a blend ratio of new slurry 306 to recycled slurry 308 during the polishing process. Thus allowing the slurry to provide for any losses in the collection process to ensure improved polishing of the substrate 108 during the CMP process. Combinations of these embodiments are also within the scope of this disclosure.

In one or more embodiments, the slurry delivery system 300 may further include a plurality of polishing fluid recycle modules 301. This embodiment allows for multiple different polishing fluids (e.g., new slurry 306 and recycled slurry 308) to be collected independently and reused only for a specific platen or platens during a CMP process.

Referring back to FIG. 2, the polishing system 200 further includes a system controller 800 to direct the operation thereof, which includes the operation of the slurry delivery system 300. In one or more embodiments, the system controller 800 may be the same as the system controller 111 of the CMP system 100 shown in FIG. 1 or, alternatively, it could be an additional system controller 800 as shown in FIG. 2, configured to direct the operation of the polishing system 200, which includes the operations of the slurry delivery system 300. The system controller 800 includes a programmable central processing unit, such as the CPU 802, which is operable with a memory 804 (e.g., non-volatile memory) and support circuits 806. The support circuits 806 are conventionally coupled to the CPU 802 and comprise cache, clock circuits, input/output subsystems, power supplies, and the like, and combinations thereof coupled to the various components of the polishing system 200, to facilitate control thereof. The CPU 802 is one of any form of general purpose computer processor used in an industrial setting, such as a programmable logic controller (PLC), for controlling various components and sub-processors of the polishing system 200. The memory 804, coupled to the CPU 802, is non-transitory and is typically one or more of readily available memories such as random access memory (RAM), read only memory (ROM), floppy disk drive, hard disk, or any other form of digital storage, local or remote.

The memory 804 is in the form of a computer-readable storage media containing instructions (e.g., non-volatile memory), which, when executed by the CPU 802, facilitates the operation of the polishing system 200. The instructions in the memory 804 are in the form of a program product such as a program that implements the methods of the present disclosure. The CPU 802 is further configured to include sensors (e.g., in line oxygen sensor 399 and pH sensor 397 within the slurry delivery system 300 in FIGS. 3A and 3B) and machine learning capabilities. The sensors of the CPU 802 are configured to measure various parameters of the fluid delivery system 300, such as pH levels, oxygen levels, and acidity levels, among others. The machine learning capabilities are capable of optimizing the amounts of the new slurry 306 dispensed from nozzle 216A that are mixed with the recycled slurry 308 dispensed from nozzle 216B to reduce the cost of polishing and the amount of maintenance time required, as well as optimizing other parameters such as pH and/or oxygen levels via in line pH sensor 397 and oxygen sensor 399, and the possibility for acid addition for pH adjustment and control.

The memory 804 is configured to store a plurality of instructions for running operations on the polishing system 200. For example, the memory 804 can hold instructions that designate what percentage of the new slurry 306 is mixed with the recycled slurry 308. The memory can hold instructions that designate a ratio of new slurry 306 to recycled slurry 308 and vary this ratio in order to optimize (i.e., maintain) a certain pH and oxygen level of the polishing mixture. The memory 804 can hold instructions that designate the rotation speed of the platen 202 around the platen axis 212 or the substrate carrier 152 around the carrier axis 210. The memory 804 can hold instructions for controlling the flow of both new and recycled slurry 306 and 308 respectively, i.e., for example, for when to change from dispensing new slurry 306 to dispensing recycled slurry 308 or vice versa. In addition, the memory 804 can hold instructions for how the polishing process should proceed in the event that the slurry delivery system 300 is undergoing maintenance or has malfunctioned.

The program code may conform to any one of a number of different programming languages. In one example, the disclosure may be implemented as a programming product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the polishing pad manufacturing methods set forth herein are performed by a combination of software routines, ASIC(s), FPGAs and, or other types of hardware implementations.

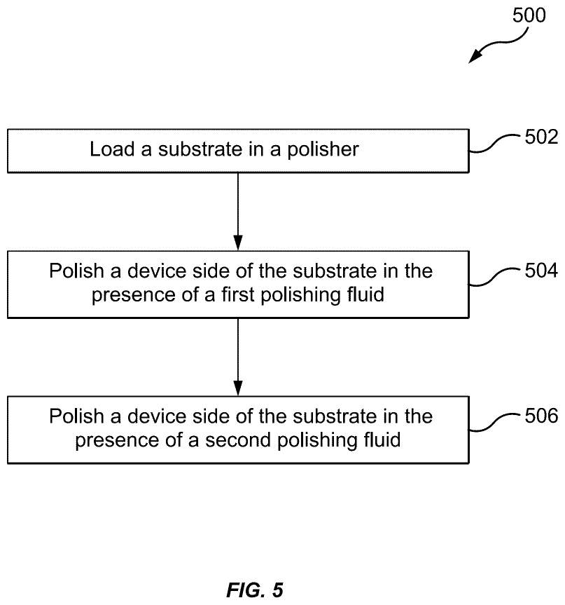

Referring to FIG. 5, a flow diagram of a method 500 of polishing a substrate 108 is illustrated. The method 500 includes operation 502 in which a substrate 108 is loaded into a polishing system (e.g., the CMP system 100 shown in FIG. 1). Referring back to FIG. 1, the loading of the substrate 108 is initiated with the substrate 108 being transferred from one of the cassettes 118 to the input module 124 by the interface robot 120 by following the operations described above in relation to FIG. 1 described earlier, culminating with the substrate 108 being loaded onto the polishing pad 126 in a horizontal orientation.

The substrate 108 may include one or more material layers and/or structures formed thereon a device side of substrate 108. For example, the device side of the substrate 108 may include one or more metal layers, one or more dielectric layers, one or more interconnection structures, one or more redistribution structures, and/or other suitable layers and/or structures. In one or more embodiments, the device side of the substrate 108 comprises a silicon material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, and other suitable silicon materials. In one example, the substrate comprises a polymeric material such as polyimide, polyamide, parylene, silicone, epoxy, glass fiber-reinforced epoxy molding compound, epoxy resin with ceramic particles disposed therein, and other suitable polymeric materials. In one or more embodiments, the substrate 108 includes a backside comprising a non-metal material, such as carbon (hereinafter “carbon side”).

Operation 504 includes urging the device side of the substrate 108 against the polishing pad 126 and exposing the device side of the substrate 108 to a first polishing fluid while rotating the platen 202 to remove material from the surface of the substrate 108. In one or more embodiments, the first polishing fluid comprises a first ratio of recycled slurry 308 to new slurry 306 that is greater than 1. That is, the flow rate of the recycled slurry 308 through nozzle 216B of dispensing arm 214 and the flow rate of the new slurry 306 through nozzle 216A of dispensing arm 214 may be adjusted (via the controller 800 as explained above) to provide a mixture or a blend ratio of recycled slurry 308, collected using the slurry delivery system 300, to new slurry 306 from the polishing source 226. During operation 504, the first polishing fluid may have a first ratio of recycled slurry 308 to new slurry 306 ranging from about 0 ml/min to about 100ml/min. In one example, the first polishing fluid initially comprises a first ratio of about 50% ml/min of recycled slurry 308 to about 50% ml/min of new slurry 306. In one example, the first polishing fluid comprises a first ratio of about 90% ml/min of recycled slurry 308 to about 10% ml/min of new slurry 306. In another example, the first polishing fluid comprises a first ratio of about 70% ml/min of recycled slurry 308 to about 30% ml/min of new slurry 306. This configuration allows for the new slurry 306 to provide for any losses in the collection process and for preferential adjustments of the ratio of the recycled slurry 308 to new slurry 306 in order to achieve improved cost and performance during the CMP process.

During operation 504, if a change is detected in the first polishing fluid, e.g., a rise in pH detected by the pH sensor 397, the ratio of recycled slurry 308 to new slurry 306 is adjusted by increasing the percentage of new slurry 306 in the first polishing fluid and thus decreasing the ratio of recycled slurry 308 to new slurry 306. Alternatively, if a drop in pH is observed, the ratio of recycled slurry 308 to new slurry 306 is adjusted by increasing the percentage of recycled slurry 308 in the first polishing fluid, thus increasing the ratio of recycled slurry 308 to new slurry 306.

In one or more embodiments, during operation 504 of method 500, the first polishing fluid includes colloidal particles dispersed in a solution comprising a dispersion agent. In one embodiment, the colloidal particles present in the first ratio of recycled slurry 308 to new slurry 306 are formed from an abrasive material such as silica (SiO₂), alumina (AL₂O₃), ceria (CeO₂), ferric oxide (Fe₂O₃), zirconia (ZrO₂), diamond (C), boron nitride (BN), and titania (TiO₂). In one embodiment, the colloidal particles are formed from silicon carbide (SiC).

The colloidal particles utilized in the first polishing fluid range in grit size from about 1 μm to about 55 μm, such as between about 1.2 μm and about 20 μm. Increasing the grit size of the colloidal particles dispersed in the first polishing fluid during block 504 may increase the rate at which material may be removed from the substrate during the mechanical grinding process during the polishing time.

A weight percentage of the colloidal particles in the first polishing fluid ranges from about 1% to about 25%, such as between about 2% and about 20%.

The dispersion agent in the first polishing fluid is selected to increase the grinding efficiency of the colloidal particles. In one embodiment, the dispersion agent is a non-ionic polymer dispersant, including but not limited to polyvinyl alcohol (PVA), ethylene glycol (EG), glycerin, polyethylene glycol (PEG), polypropylene glycol (PPG), and polyvinylpyrrolidone (PVP). In one example, the dispersion agent is PEG with a molecular weight up to 2000. For example, the dispersion agent may be PEG 200, PEG 400, PEG 600, PEG 800, PEG 1000, PEG 1500, or PEG 2000. The dispersion agent is mixed with water or an aqueous solvent comprising water in a ratio between about 1:1 volume/volume (v/v) and about 1:4 (v/v) dispersion agent: water or aqueous solvent.

In one or more embodiments, the first polishing fluid (i.e., the first ratio of recycled slurry 308 to new slurry 306) disposed on the device side of the substrate 108 during block 504, further includes a pH adjustor, such as potassium hydroxide (KOH), tetramethylammonium hydroxide (TMAH), ammonium hydroxide (NH₄OH), nitric acid (HNO₃) or the like.

During block 504, the device side of the substrate 108 and the polishing pad, such as polishing pad 126, are contacted at a pressure less than about 15 pounds per square inch (psi). Increasing the pressure at which the polishing pad and substrate surface contact generally increases the rate at which material may be removed from the substrate during the polishing process.

In one or more embodiments, the platen is rotated at a velocity from about 50 rotations per minute (rpm) to about 100 rpm, and the substrate carrier is rotated at a velocity from about 50 rpm to about 100 rpm.

After the completion of block 504, the device side of the substrate 108, now having a reduced thickness, is exposed to the presence of a second polishing fluid during operation 506. The second polishing fluid has a second ratio of recycled slurry 308 collected from the slurry delivery system 300 during block 504 to new slurry 306 from the polishing fluid source 226. In one or more embodiments, the second ratio of recycled slurry 308 to new slurry 306 is equal or smaller than the first ratio of recycled slurry 308 to new slurry 306 from operation 504. That is, the second ratio comprises the same or a higher amount of new slurry 306 from the polishing fluid source 226. During operation 506, the second polishing fluid may have a second ratio of recycled slurry 308 to new slurry 306 ranging from about 0 ml/min to about 100 ml/min. In one example, the second polishing fluid comprises a first ratio of about 90% ml/min of recycled slurry 308 to about 10% ml/min of new slurry 306. In one example, the second polishing fluid comprises a first ratio of about 60% ml/min of recycled slurry 308 to about 40% ml/min of new slurry 306. In yet another example the second polishing fluid comprises a second ratio of about 30% ml/min of recycled slurry 308 to about 70% ml/min of new slurry 306 during the polishing process of block 506. In one or more embodiments, the second polishing fluid comprises 100% new slurry 306.

As described above during operation 504, if a change is detected in the second polishing fluid, e.g., a rise in pH, the ratio of recycled slurry 308 to new slurry 306 is adjusted by increasing the percentage of new slurry 306 and thus decreasing the ratio of recycled slurry 308 to new slurry 306. This configuration provides the beneficial advantage of compensating for any losses during the collection process in block 504 while using recycled slurries to reduce the operational costs during the CMP process.

In one embodiment, the colloidal particles utilized for the second polishing fluid range in grit size from about 20 nm to about 500 nm, such as between about 25 nm and about 300 nm. Decreasing the grit size of the colloidal particles dispersed in the second polishing fluid controls the finished surface quality of the substrate 108.

The colloidal particles utilized in the second polishing fluid are formed from SiO2, AL₂O₃, CeO₂, Fe₂O₃, ZrO₂, C, BN, TiO₂, SiC, and the like. In one embodiment, the colloidal particles utilized in the second polishing fluid are formed from the same material as the colloidal particles in the first polishing fluid. In another embodiment, the colloidal particles utilized in the second polishing fluid are formed from a different material than the colloidal particles in the first polishing fluid.

A weight percentage of the colloidal particles in the second polishing fluid ranges from about 1% to about 30%, such as between about 1% and about 25%.

In some embodiments, the colloidal particles are dispersed in a solution including water, alumina (Al₂O₃), KOH, and the like. The second polishing fluid may have a pH in a range of about 4 to about 10, such as between about 5 and about 10. For example, the polishing fluid has a pH in a range of about 7 to about 10, such as about 9. As described above, one or more pH adjustors, and additionally or alternatively, new slurry 306, may be added to the second polishing fluid to adjust the pH of the second polishing fluid to a desired level. For example, the pH of the second polishing fluid may be adjusted by the addition of TMAH, NH₄OH, HNO₃, or the like.

During block 506, the device side of the substrate 108 and the polishing pad are contacted at a pressure less than 15 psi. Smoothening of the device side of the substrate 108 may be performed with a second polishing process having a pressure of about 10 psi or less, for example, from about 2 psi to about 10 psi.

In one embodiment, the platen is rotated during the second polishing process at a velocity from about 50 rpm to about 100 rpm, and the substrate carrier is rotated at a velocity from about 50 rpm to about 100 rpm.

In one or more embodiments, operations 504 and 506 may be performed on a common polishing pad or on different polishing pads, such as the polishing pad 126 shown in FIG. 2 in the CMP processing system shown in FIG. 1, with one or multiple platens and with one or more slurry delivery systems 300 as shown in FIGS. 3A-3B.

In one or more embodiments, operations of method 500 are performed in multiple platens, corresponding to CMP stations 128, 130, and 132 disposed in the environmentally controlled enclosure 188 of system 100 shown in FIG. 1. During this multiple platen operation, a device side of the substrate 108 is polished sequentially on three different CMP stations, e.g., station 128, followed by station 130, and culminating with station 132 while the pH and oxygen levels are closely monitored using the pH sensor 397 and oxygen sensor 399 and adjusted by the system controller 800 or system controller 111 to maintain a desired level. For example, when using the system 100, operation 504 may be performed on both first station 128 and second station 130 in the presence of the first polishing fluid, and operation 506 may be performed on third station 132 in the presence of the second polishing fluid.

Polishing the device side of the substrate 108 on the first platen or first polishing station followed by polishing the device side of the substrate 108 in the second platen or second polishing station in the presence of the first polishing fluid comprising a first ratio of recycled slurry 308 to new slurry 306, has the advantage of reducing any roughness or unevenness caused by the polishing on the first platen or the first polishing station for a first period of time while decreasing the operational cost by recycling and reusing the new slurry 306 from the polishing fluid source 226.

Using a higher amount of new slurry 306 in the second polishing fluid during block 506 results in improved surface quality and optimization of cost during the CMP process. In one or more embodiments, the polishing on each platen removes the same amount of material from the device side of the substrate 108. In one instance, the removal of material from the device side of the substrate during each polishing process on each of the platens as described above can be from about 25% to about 33%, such as of about 30%.

The polishing method 500 depicted in FIG. 5, as explained above, leads to improved substrate 108 polishing, since the sequential polishing of the device side of the substrate 108 in one or more platens during block 504 in the presence of the first polishing fluid, followed by exposure to a second polishing fluid in a third platen during block 506 leads to an improved removal rate of substrate material and finished surface quality compared to conventional planarization techniques and polishing processes while simultaneously decreasing the operational costs of the CMP process by reusing the new slurry 306 from the from the polishing fluid source 226 during the polishing of the substrate 108. Furthermore, by controlling and configuring the ratio of recycled slurry 308 to new slurry 306 during the polishing of the device side of the substrate 108 during the CMP system such that the polishing in the last platen or planarizing station has a higher percentage of new slurry 306 improves the finished surface quality, while optimizing operational costs.

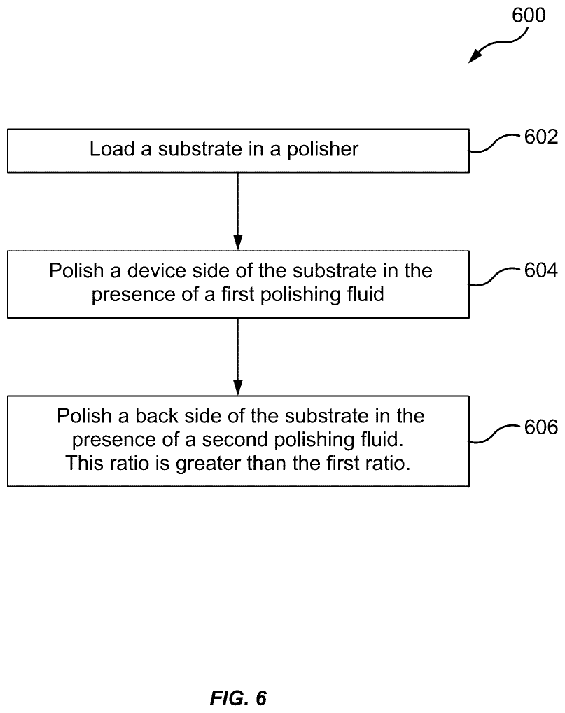

In one or more embodiments, the polishing of the device side of the substrate 108 does not conclude the polishing process and further polishing (e.g., of the backside) of the substrate 108 is needed to complete the CMP process. FIG. 6 provides a flow diagram of such a method 600 of polishing a device side of a substrate 108 in the presence of a first polishing fluid followed by polishing a backside of a substrate 108 in the presence of a second polishing fluid.

More specifically, method 600 begins with block 602 by loading the substrate in a polisher (e.g., the CMP system shown in FIG. 1). The operation of block 602 is similar to that performed and explained for that of block 502 of method 500 and thus the details will not be further discussed for the sake of brevity.

During block 604, the device side of the substrate 108 is polished in the presence of a first polishing fluid in the CMP polishing system 100, the first polishing fluid comprising of a first ratio of recycled slurry 308 to new slurry 306 that is equal to or greater than 1. During operation 604, the first polishing fluid may have a first ratio of recycled slurry 308 to new slurry 306 ranging from about 0 ml/min to about 100 ml/min. In one example, the first polishing fluid initially comprises a first ratio of about 50% ml/min recycled slurry 308 to about 50% ml/min of new slurry 306. During the polishing process, if a change is detected in the first polishing fluid, e.g., a rise in pH detected by the pH sensor 397, the ratio of recycled slurry 308 to new slurry 306 is adjusted by increasing the percentage of new slurry 306 in the first polishing fluid and thus decreasing the ratio of recycled slurry 308 to new slurry 306. In one example, the first polishing fluid comprises a first ratio of about 70% ml/min of recycled slurry 308 to about 30% ml/min of new slurry 306. In another example the first polishing fluid comprises a first ratio of about 85% ml/min of recycled slurry 308 to 15% ml/min of new slurry 306. The first polishing of the substrate during block 604 may be performed by the use of the processes and chemistries described above with respect to block 504 of method 500 and thus the details will not be further discussed for the sake of brevity.

Once block 604 is completed, the substrate 108 is returned to the transfer station 136 from where the robot 104 may transfer the substrate 108 from the planarizing module 106 to the input module or queuing station 124 while rotating the substrate to a vertical orientation. The substrate handler 166 then retrieves the substrate 108 from the queuing station 124 and transfers the substrate 108 through one or more cleaning modules 160 of the cleaning system 116. In one or more embodiments, the substrate handler 166 retrieves the substrate 108 from the queuing station 124 and transfers the substrate 108 through the cleaning modules 160 of the cleaning system 116. Once the cleaning of substrate 108 is completed, the cleaned substrate 108 is transferred to the queuing station 124 by the substrate handler 166 to be received by the loading robot 104 and transferred to the transfer station 136 of the planarizing module 106 to complete the polishing process.

The polishing process of method 600 is completed with operation of block 606 by polishing the backside of the substrate 108 in the presence of a second polishing fluid. The second polishing fluid comprises a second ratio of recycled slurry 308 to new slurry 306 that is greater than the first ratio of recycled slurry 308 to new slurry 306. During operation 606, the second polishing fluid may have a second ratio of recycled slurry 308 to new slurry 306 ranging from about 0 ml/min to about 100 ml/min. In one example, the second polishing fluid comprises a second ratio of about 70% ml/min of recycled slurry 308 to about 30% ml/min of new slurry 306. In another example the first polishing fluid comprises a first ratio of about 85% ml/min of recycled slurry 308 to about 15% ml/min of new slurry 306. In one or more embodiments, the second polishing fluid comprises 100% ml/min of recycled slurry 308. Polishing the backside of the substrate 108 with the second polishing fluid comprising a ratio of recycled slurry 308 to new slurry 306 that is greater than 1 (i.e., a high percentage of recycled slurry 308) decreases the cost of operating the CMP polishing system by allowing the new slurry 306 to be used for the polishing of the device side of the substrate 108 to improve the resulting surface quality.

The present disclosure contemplates variations of method 600 of FIG. 6 to fall within its scope. For example, in one or more embodiments, the backside of the substrate 108 is first polished for a first period of time in the presence of the second polishing fluid comprising a second ratio of new slurry 306 to recycled slurry 308 in block 606 before being polished for a second period of time during the operations in block 604 in the presence of the first polishing fluid comprising a first ratio of new slurry 306 to recycled slurry 308.

Beneficially, the methods and systems provided herein improve the operational cost of the CMP process by controlling and adjusting the ratio of recycled slurry 308 to new slurry 306 during the polishing process of a substrate.

While the foregoing is directed to embodiments of the present disclosure, other and further embodiments of the disclosure may be devised without departing from the basic scope thereof, and the scope thereof is determined by the claims that follow.

What is claimed is:

1. A method for polishing a substrate, the method comprising:
polishing a device side of the substrate in the presence of a first polishing fluid, the first polishing fluid comprising a first ratio of recycled slurry to new slurry; and
polishing the device side of the substrate in the presence of a second polishing fluid, the second polishing fluid comprising a second ratio of recycled slurry to new slurry that is smaller than the first ratio of recycled slurry to new slurry.

2. The method of claim 1, wherein polishing the device side of the substrate in the presence of the first polishing fluid is performed on a first polishing platen, and polishing the device side of the substrate in the presence of the second polishing fluid is performed on a second polishing platen.

3. The method of claim 1, wherein polishing the device side of the substrate in the presence of the first polishing fluid is performed on a first polishing platen and a second polishing platen, and polishing the device side of the substrate in the presence of the second polishing fluid is performed on a third polishing platen.

4. The method of claim 1, wherein the first ratio is greater than 1.

5. The method of claim 1, wherein the first ratio is between 0 ml/min 100 ml/min.

6. The method of claim 1, wherein the second ratio is less than 1.

7. The method of claim 1, wherein the second ratio is between 0 ml/min 100 ml/min.

8. The method of claim 1, wherein the second ratio comprises 100% new slurry.

9. A method for polishing a substrate, the method comprising:
polishing a device side of the substrate in the presence of a first polishing fluid, the first polishing fluid comprising a first ratio of recycled slurry to new slurry; and
polishing a back side of the substrate in the presence of a second polishing fluid, the second polishing fluid comprising a second ratio of recycled slurry to new that is higher than the first ratio of recycled slurry to new slurry.

10. The method of claim 9, wherein the first ratio is between 0 ml/min 100 ml/min.

11. The method of claim 9, wherein the second ratio comprises 100% recycled slurry.

12. The method of claim 9, wherein polishing the device side of the substrate in the presence of the first polishing fluid is performed on a first polishing platen, and polishing the back side of the substrate in the presence of the second polishing fluid is performed on a second polishing platen.

13. The method of claim 9, wherein polishing the device side of the substrate in the presence of the first polishing fluid is performed on a first polishing platen and a second polishing platen, and polishing the back side of the substrate in the presence of the second polishing fluid is performed on a third polishing platen.

14. A substrate polishing system, comprising:
one or more polishers, each having a polishing pad disposed on a platen;
one or more slurry delivery systems operable to control a ratio of recycled slurry to new slurry delivered to each polishing pad; and
a controller coupled to the one or more polishers and the one or more slurry delivery systems, the controller comprising one or more processors and one or more non-transitory machine readable media storing instructions that when executed by the one or more processors cause the substrate polishing system to:
polish a substrate in the presence of a first polishing fluid, the first polishing fluid comprising a first ratio of recycled slurry to new slurry; and
polish the substrate in the presence of a second polishing fluid, the second polishing fluid comprising a second ratio of recycled slurry to new slurry that is different than the first ratio of recycled slurry to new slurry.

15. The substrate polishing system of claim 14, wherein a device side of the substrate is polished in the presence of the first polishing fluid and in the presence of the second polishing fluid.

16. The substrate polishing system of claim 15, wherein polishing the device side of the substrate in the presence of the first polishing fluid is performed on a first polishing platen, and polishing the device side of the substrate in the presence of the second polishing fluid is performed on a second polishing platen.

17. The substrate polishing system of claim 15, wherein polishing the device side of the substrate in the presence of the first polishing fluid is performed on a first polishing platen and a second polishing platen, and polishing the device side of the substrate in the presence of the second polishing fluid is performed on a third polishing platen.

18. The substrate polishing system of claim 14, wherein a backside of the substrate is polished in the presence of the second polishing fluid.

19. The substrate polishing system of claim 14. wherein the first ratio is between 0 ml/min-100 ml/min.

20. The substrate polishing system of claim 14. wherein the second ratio is between 0 ml/min-100 ml/min.
